(19) United States
(12) Patent Application Publication
(10) Pub. No.: US 2026/0164605 A1
(43) Pub. Date: Jun. 11, 2026

(54) COOLING SYSTEM FOR THE LIQUID IMMERSION COOLING OF ELECTRONIC COMPONENTS

(71) Applicant: Wieland-Werke AG, Ulm (DE)

(72) Inventors: Achim GOTTERBARM, Dornstadt (DE); Harald GAIBLER, Rottenacker (DE); Philipp Hofmann, Weissenhorn (DE); Verena OBST, Neu-Ulm (DE); Michael SCHEUSS, Köln (DE)

(21) Appl. No.: 19/127,232

(22) PCT Filed: Oct. 26, 2023
(86) PCT No.: PCT/EP2023/079871

§ 371 Date: May 5, 2025

(30) Foreign Application Priority Data
Nov. 24, 2022 (DE) 10 2022 004 390.4

(51) Int. Cl. H05K 7/20

(52) U.S. Cl. CPC H05K 7/20327; H05K 7/203; H05K 7/20318

(57) ABSTRACT

A cooling system for liquid immersion cooling of electronic components, having a vessel filled with two-phase heat transfer fluid, in a liquid phase of which electronic components are immersed, a heat exchanger device in a gas space of the vessel for forming liquid heat transfer fluid, a condenser unit outside the vessel and connected by a fluid line as a feed line and return line to the gas space of the vessel for mass transfer of gaseous medium to the condenser unit and condensed heat transfer fluid to the vessel. The condenser unit has an outlet for discharging a residual gas phase and the fluid line as the feed line and return line of the condenser unit is a single tube line connected to the vessel.

The invention relates to a cooling system for the liquid immersion cooling of electronic components in accordance with the preamble of claim 1.

In the form of two-phase immersion cooling systems, for example, cooling systems for liquid immersion cooling are an active cooling solution for electronic components, which generate a large amount of heat during operation. As the components are immersed in a two-phase heat transfer fluid, which usually has a low boiling point, the heat generated by the electronic component can evaporate the surrounding liquid heat transfer fluid, thereby dissipating heat from the electronic component. A condenser device liquefies the gaseous heat transfer fluid, which is then returned to the reservoir for cooling.

U.S. Pat. No. 10,512,192 B2 discloses a two-phase immersion cooling system having a cooling basin. A condenser chamber, in which the gaseous fluid formed during the cooling process is condensed, is connected to the liquid fluid in the cooling basin. In this case, a vapor redirection structure is arranged above the heat-generating electronic components located within the cooling medium in the cooling basin. The evaporated fluid is directed by means of the vapor redirection structure into the condensation chamber for liquefaction. The condensation chamber is located completely within the cooling basin.

In this context, a cooling system for computer components is known from U.S. Pat. No. 10,477,726 B1. In a pressure-controlled vessel there is a heat-conducting dielectric heat transfer fluid in liquid and gaseous phase, which has a boiling point below 80° C. at atmospheric pressure. Arranged in the vessel are computer components, which are immersed at least partially in the liquid phase of the heat transfer fluid. By means of a condenser, the dielectric gas phase fluid evaporated by the generation of heat by the computer components is condensed to form dielectric liquid phase fluid. In the interior of the pressure-controlled vessel, the internal pressure is reduced to as little as 650 hPa. By controlling the pressure in the vessel at which the system operates, the user can influence the temperature at which the dielectric liquid evaporates. It is thereby possible to obtain an increased cooling capacity. The operation of a computer system within a pressure-controlled vessel at an operating pressure which differs from ambient pressure generally requires adaptation of the design of the system as a whole.

US 2021/0 153 392 A1 discloses a cooling system comprising a vessel which can be filled with two-phase heat transfer fluid as a coolant, in the liquid phase of which electronic components can be immersed. The vessel has a gas space above the surface of the liquid heat transfer fluid. Arranged above the vessel is a separate external condenser device, which is configured in such a way that it condenses the vapor phase of the heat transfer fluid and feeds it as liquid coolant back into the vessel containing the electronic components. For this purpose, the system comprises return and feed lines, which are connected both to the condenser device and to the vessel in order to form a heat exchange loop. The system furthermore comprises a collecting vessel, which is arranged on the supply line and is configured in such a way that it collects the condensed liquid heat transfer fluid before the coolant is fed to the vessel. This accumulator also offers a reserve cooling capacity for the cooling system.

EP 3 453 235 B 1 discloses a cooling system for the immersion cooling of electronic components, comprising a pressure-tight tank configured to hold heat transfer fluid in liquid form, in which the electronic equipment is immersed. In addition, there is a vapor space above a surface of the liquid heat transfer fluid. Arranged outside the pressure-tight tank is a condenser, wherein the condenser has an inlet which is connected by a riser tube to the vapor space and is configured to receive heat transfer fluid vapor. In addition, the condenser has a tightly closable vapor outlet for residual gases and a condensate outlet with a condensate return line to the tank. The condensate return line is configured in such a way that condensed heat transfer fluid can flow through it from the condensate outlet back to the tank. Within the tank, there may also already be further condenser tubes for liquefying gaseous heat transfer fluid.

It is the underlying object of the invention to further develop a cooling system for liquid immersion cooling of electronic components in respect of a heat exchanger device for the heat transfer fluid.

The invention is described by the features of claim 1. The further, dependent claims relate to advantageous embodiments and developments of the invention.

The invention includes a cooling system for the liquid immersion cooling of electronic components. The cooling system comprises a vessel, the interior of which can be filled with two-phase heat transfer fluid, in the liquid phase of which electronic components can be immersed. The vessel has a gas space above the surface of the liquid heat transfer fluid. In addition, the cooling system comprises a heat exchanger device in the gas space of the vessel for the purpose of forming liquid heat transfer fluid. The cooling system furthermore comprises a condenser unit arranged outside the vessel, wherein the condenser unit is connected by means of a fluid line as a feed line and return line to the gas space of the vessel for the mass transfer of gaseous medium to the condenser unit and condensed heat transfer fluid to the vessel, wherein the condenser unit has an outlet, via which a residual gas phase can be discharged. According to the invention, the fluid line as the feed line and return line of the condenser unit is a single tube line with a suitable line cross section or a double-tube line, which is connected to the vessel.

The vessel can be of pressure-tight design. The vessel can advantageously be embodied as a pressure vessel which can be operated under a vacuum and/or excess pressure. An increased cooling capacity can be achieved by controlling the pressure in the vessel at which the cooling system operates.

The heat exchanger device in the gas space preferably consists of at least one tube bundle comprising a plurality of heat exchanger tubes arranged in relation to one another. A tube bundle can have a plurality of heat exchanger tubes arranged parallel to one another, with two tube sheets at the ends. In the vessel, the tube bundle or heat exchanger tubes can be arranged symmetrically or, alternatively, asymmetrically or along diagonals with respect to the vessel wall.

The feed line and the return line of the condenser unit may also be a single tube line with a suitable line cross section, which is connected to the vessel. Such that both mass transfer of gaseous medium and mass transfer of condensed heat transfer fluid takes place via this single tube line. Here, a suitable line cross section is dimensioned in such a way that the gaseous and liquid media flowing in opposite directions in the same tube do not hinder one another in terms of their flow characteristic. Practical experience shows that condensed heat transfer fluid flows along the inner tube wall to the vessel on account of the wetting properties, and gaseous heat transfer fluid flows to the condenser in the opposite direction in the region of the center of the tube.

Alternatively, the feed line and the return line of the condenser unit may also be a double-tube line, which is connected to the vessel. Such that mass transfer of gaseous medium takes place via an inner feed line and mass transfer for condensed heat exchange fluid takes place via a return line surrounding the inner feed line. In this case, a suitable line cross section of the feed line and of the return line is dimensioned in such a way that the gaseous and liquid media flowing in the respective line can flow with low resistance in their flow characteristic. Practical experience shows that, on account of the smaller volume, condensed heat transfer fluid requires a smaller line cross section of the casing tube of the return line than the line cross section of the inner feed line for gaseous heat transfer fluid.

The heat exchanger tubes are preferably ribbed tubes, which are produced from smooth tubes and subjected to a forming process. They are suitable particularly as components in highly efficient, compact and extremely stable heat exchangers with a high heat transfer coefficient. The tube surfaces are optimized to the specific heat transfer needs of the application. With a large selection of materials, which include copper, copper alloys, steels, titanium or titanium alloys, it is ensured that suitable material for the respective requirements, especially in respect of durability and deformability, is available for different needs.

The two-phase heat transfer fluid, also referred to as refrigerant, forms the outer fluid situated in the vessel, in the liquid fraction of which the electronic components are immersed. The internal fluid situated in the heat exchanger tubes is usually a single-phase heat transfer medium, e.g. process water, glycol or a heat transfer oil. In this case too, however, a two-phase medium can be used in combination with a refrigerating circuit.

In the vessel, the electronic components are arranged in a manner suitable for cooling in a bath of liquid heat transfer fluid and are cooled by evaporation of the liquid fluid. During this process, the fraction of gases that cannot be condensed can be effectively removed from the system before or during start-up.

In the embodiment according to the invention, the computing components and immersion cooling equipment as well as the associated power supplies, network connections, wiring connections and the like can be arranged in the vessel, which has an internal pressure that deviates from ambient pressure during operation.

In this context, it is also advantageous to combine power, water, vacuum and network connections in a bundle of lines in order to minimize the passages into the vessel and in order to reduce the risk of leaks, especially if the system is under a vacuum or excess pressure during operation.

In advantageous embodiments, the vessel is held at as much as 200 hPa below the ambient atmospheric pressure during operation, and this contributes to lowering the boiling point of the two-phase heat transfer fluid and thereby reducing the operating temperature of the computer chips and other components. In a number of special embodiments, the pressure-controlled vessel can have an even lower pressure of as much as 500 hPa below ambient pressure.

Embodiments according to the invention of the cooling system comprise a vessel which is designed in such a way that a two-phase liquid immersion cooling system is used. The vessel contains a basin of dielectric cooling fluid, a heat exchanger device and an external condenser unit for condensing the dielectric fluid from the gaseous phase to a liquid. The condenser unit, which is situated outside the vessel, is intended to condense the residue of gaseous heat transfer fluid, which also contains certain fractions of air and water vapor, into as high as possible a fraction of the liquid heat transfer fluid. Ideally, the residual heat transfer fluid is condensed almost completely out of the gas phase, leaving substantially only air and water vapor remaining as a residual gas phase. The aim in precipitating liquid heat transfer fluid here is to keep the water vapor in the gas phase by means of a suitable cooling capacity of the system. This residual gas mixture is discharged from the cooling system via an outlet of the condenser unit.

In addition, devices for holding computer components and for distributing power from the power supply system to the equipment and components situated within the vessel can be provided. It is self-evident that a large number of specialized connections are used to operate a computer system within a vessel which is, for example, held under a vacuum. Some embodiments of the system according to the invention can use a series of fiber-optic interfaces, which allow connectivity in the vessel and distribute the fibers between the various holding devices to the electronic components. Some embodiments of the vessel can contain monitoring sensors for reliable operation. These sensors can comprise temperature sensors, fluid level sensors, pressure sensors, position sensors, electric sensors and/or cameras in order to ensure and to automate the operation of the system.

These systems can comprise, for example, pressure sensors within the pressure-controlled vessel, which monitor the pressure in order to ensure that there are no significant leaks. Gas sensors, which are arranged on the outside of the pressure-controlled vessel and detect the presence of any dielectric vapor that may be present and is escaping from the pressure-controlled vessel can likewise be provided.

In addition, the cooling system can advantageously have a control device, which is designed to control the operation of the fluid circulation system, e.g. as a function of the temperature of the two-phase heat transfer fluid, and the pressure conditions in the vessel.

A fitting system, by means of which, for exchange, electronic components can be transported from the lock device to the operating position, can advantageously be set up. A fitting system can comprise robot arms or linear drive devices. Given a suitable design of the device, exchange of the components can be carried out by means of a fully automatic fitting system. Alternatively, gloves may also be arranged at suitable vessel openings to allow electronic components to be transferred from the lock device to the operating position. This enables fitting by manual access to the interior of the vessel.

In one advantageous embodiment of the invention, the fluid line can have a structured internal surface. In the case of a single tube line, the internal surface can have rib-type, channel-type or porous structural features or raised portions, by means of which the condensed heat transfer fluid is guided along the surface of the inside of the tube to the vessel inlet. In the case of a double-tube line routed to the vessel, the internal surface of the return line situated on the inside is of rib-type, channel-type or porous design or designed with raised portions in order to selectively guide the condensed heat transfer fluid away in the same manner. In contrast, the internal surface of the outer tube, surrounding the return line, for carrying the gaseous heat transfer fluid may also be of smooth design.

In one particularly advantageous embodiment of the cooling system according to the invention, the structured internal surface of the fluid line can be helically encircling ribbing to guide the condensed heat transfer fluid to the vessel. Given a suitable pitch of the ribs, the fluid can be guided in a spiral by means of gravity on the inner tube wall.

In one advantageous embodiment, the fluid line can be a tube line or a double-tube line running at an angle of inclination to the action of gravity. As a result, condensed heat transfer fluid flows back to the vessel at least over part of the inner wall on account of gravity. In the case of a single tube line, the mass transfer of the condensed heat transfer fluid thereby takes place on the lower part of the inner wall, whereas the gaseous heat transfer fluid is guided in countercurrent flow along the upper part of the inner wall.

The Angle of Inclination of the Fluid Line Relative to the action of gravity is advantageously at least 2° and preferably at least 5° and particularly preferably at least 15°. Even with such small angles of inclination, condensed heat transfer fluid is prevented from accidentally falling freely and in an uncontrolled manner in the interior of the tube during return to the vessel. Particularly in the case of a single tube line, it is possible to suppress uncontrolled or turbulent flow which would disrupt the counterflow of the gaseous heat transfer fluid.

In one preferred embodiment of the invention, the feed lines, return lines and/or the outlet can be closable or openable individually or in combination with one another by valves. For suitable process management, individual valves are opened when required in order to transfer gaseous medium or liquid heat transfer fluid. The feeding and/or discharge can take place cyclically or else in a continuous mode. In particular, the valve switching at the outlet is adjusted to ensure that as little as possible or even no heat transfer fluid escapes from the cooling system.

In one advantageous embodiment of the invention, a collecting vessel, via which the residual gas phase can be discharged, is connected downstream of the outlet. This vessel ensures that no air can enter the cooling system from the environment. The vessel can be an expandable elastic carboy or a bellows of variable volume.

A drying unit for separating water vapor from the gas phase can advantageously be arranged between the outlet and the collecting vessel. The pressure situation in the entire cooling system may change in the event of a load reversal, for example. If required, external air or residual gas can then be introduced into the cooling system by means of the collecting vessel, via the drying unit, for pressure compensation. Water vapor is then eliminated by chemical binding by means of the drying unit. Silica gel is suitable for such drying units.

In one advantageous embodiment of the invention, a vacuum pump, via which the residual gas phase can be discharged, is connected downstream of the outlet. In this case, the residual gas phase consisting of water vapor and air can also be under a vacuum at the outlet relative to the environment since a direction of flow of the residual gas toward the outside is always ensured by means of a vacuum pump.

The heat exchanger device and the condenser unit can advantageously have a common supply unit for a single-phase heat transfer medium for the purpose of cooling. Thus, both units are at a unitary temperature level which is suitable for the process of separating off the heat exchanger fluid.

The quantity distribution of the single-phase heat transfer medium for cooling for the heat exchanger device and the condenser unit of the common supply unit can advantageously be accomplished by means of active control of the volume flow of the single-phase heat transfer medium.

A multiway valve, in particular a three-way valve, is particularly suitable for active control of the volume flow. Alternatively or in combination, it is also additionally possible to incorporate a restrictor or a frequency-controlled pump for control of the volume flow into the supply unit. It is thereby possible to match and control the cooling capacities of the heat exchanger device and of the condenser unit in a suitable manner with respect to one another by means of a supplier unit.

In one advantageous embodiment of the invention, a cooling device can be arranged at least partially on the fluid line. This can be a cooling tube wound spirally around the fluid line or a cooling sleeve. This is an effective means of preventing reheating of the liquid fluid beyond the boiling point by the warmer gaseous fluid flowing in the opposite direction. In particular, the temperature of the liquid fluid flowing along the inner wall of the fluid line is in this way further reduced.

Exemplary embodiments of the invention are explained in greater detail by means of the schematic drawings.

### In the Drawings:

FIG. 1 shows a schematic view of a cooling system with a condenser unit and a tube line as a fluid line, and

FIG. 2 shows another schematic view of a cooling system with a condenser unit and a double tube line as a fluid line.

In all the figures, mutually corresponding parts are provided with the same reference signs.

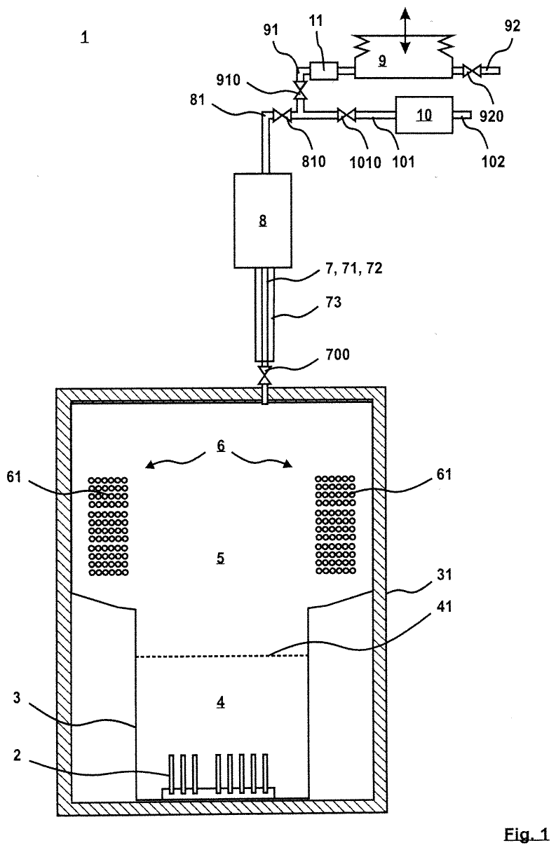

FIG. 1 shows a schematic view of a cooling system 1 omprising a condenser unit 8 and a tube line 7 as a fluid line for the liquid immersion cooling of electronic components 2. The cooling system 1 comprises a vessel 3, which is filled in the interior with two-phase heat transfer fluid during operation. The two-phase heat transfer fluid represents the outer fluid situated in the vessel 3, with a liquid heat transfer fluid fraction 4, in which the electronic components 2 are immersed, and a gas space 5 containing the gaseous heat transfer fluid fraction. In the vessel 3, a heat exchanger device 6 is arranged in the gas space 5 of the vessel 3 for the purpose of forming liquid heat transfer fluid 4.

In this advantageous embodiment, the heat exchange device 6 in the gas space 5 consists of tube bundles 61, each having a plurality of heat exchanger tubes arranged parallel to one another.

In the embodiment illustrated in FIG. 1, the vessel 3 is somewhat tapered in the region of the liquid heat transfer fluid 4 in that the vessel wall projects inward and opens out only in the gas space 5. The shape of the vessel 3 is supported by a metal profile frame 31. Consequently, the vessel 3 is already surrounded by a stabilizing external frame.

A condenser unit 8 is arranged outside the vessel 3 and above the latter. The condenser unit 8 is connected to the gas space 5 of the vessel 3 for mass transfer of gaseous medium and condensed heat transfer fluid between the vessel 3 and the condenser unit 8 by means of a fluid line 7 as a feed line 71 and return line 72. In the variant illustrated in FIG. 1, the fluid line 7 as the feed line 71 and return line 72 of the condenser unit 8 is embodied in the form of a single tube line with a suitable line cross section.

A valve 700 is optionally installed in the fluid line 7 for the purpose of controlling the mass transfer. Via the valve 700, a gaseous mixture of substances consisting of heat transfer fluid, air and water vapor is in this way drawn off from the vessel 3, either cyclically or continuously. Via the same valve 700, liquid heat transfer fluid is returned to the vessel 3.

In FIG. 1, a cooling device 73 is arranged on the fluid line 7. In the embodiment illustrated, the cooling device 73 is a cooling sleeve, through which a coolant flows during operation in order to additionally cool the outside of the fluid line 7 and thus the liquid fluid flowing on the inside. In particular, the liquid fluid in contact with the inner wall of the fluid line 7 is in this way held effectively at a temperature below the boiling point.

The residual gas phase can be fed via a feed line 91 with a valve 910 to a collecting vessel 9, which can be designed as a bellows of expandable volume for generating a vacuum. If the valve 910 leading to the collecting vessel 9 is closed during operation, the residual gas can be discharged via the discharge line 92 of the collecting vessel 9 when the valve 920 is open.

To additionally separate off water vapor, a drying unit 11 for separating water vapor from the gas phase is arranged between the outlet 81 and the collecting vessel 9. Depending on the pressure situation, the residual gas phase can be discharged directly to the environment.

Alternatively, however, the residual gas phase can also be discharged via a vacuum pump 10. For this purpose, the outlet 81 is connected via a feed line 101 to a vacuum pump 10, which, by way of a valve control arrangement 1010, controls the residual gas flow to the outside by means of a discharge line 102 of the vacuum pump 10.

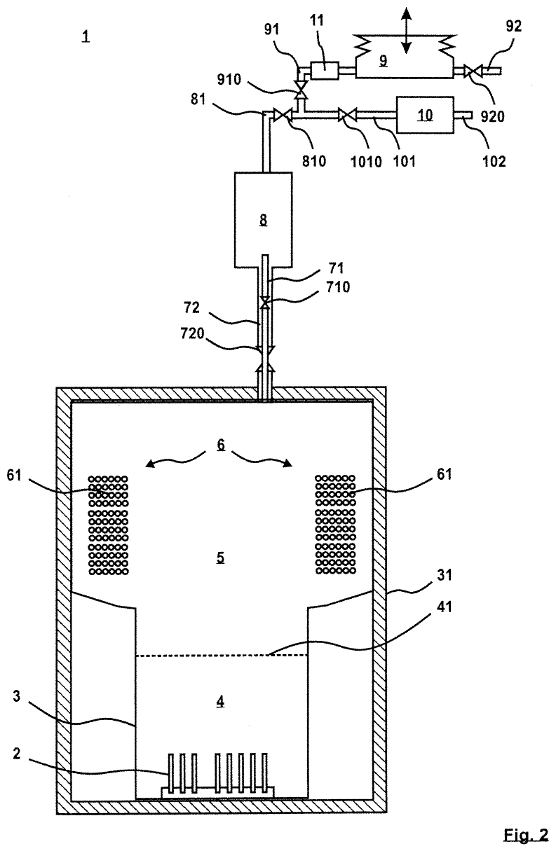

FIG. 2 shows a schematic view of a cooling system 1 comprising a condenser unit 8 and a double-tube line 7 as a fluid line for the liquid immersion cooling of electronic components 2. As an alternative to the embodiment shown in FIG. 1, the double-tube line serves as a feed line 71 for gaseous medium to the condenser unit 8 and as a return line 72 for condensed heat transfer fluid to the condenser unit 8, which is connected to the vessel 3. Mass transfer of gaseous medium takes place via the inner feed line 71. Mass transfer of condensed heat transfer fluid takes place via a return line 72 surrounding the inner feed line 71. In this arrangement, the inner feed line 71 can be made somewhat longer at the inlet into the condenser unit 8 than the surrounding return line 72. This ensures that, during the operation of the system, the condensed heat transfer fluid enters only the return line 72 and does not accidentally enter the feed line 71 projecting into the condenser unit 8.

The feed line 71 can be closed and opened individually by a valve 710, and the return line 72 can be closed and opened individually by another valve 720, or they can be closed and opened in combination. For suitable process management, individual valves are opened when required in order to transfer gaseous medium or liquid heat transfer fluid.

### LIST OF REFERENCE SIGNS

1 cooling system
2 electronic component
3 vessel
31 metal profile frame
4 liquid heat transfer fluid
41 surface of the liquid fluid in the vessel
5 gaseous heat transfer fluid, gas space
6 heat exchange device
61 tube bundle
7 fluid line
700 valve of the fluid line
71 feed line
710 valve of the feed line
72 return line
720 valve of the return line
73 cooling device
8 condenser unit
81 outlet
810 outlet valve
9 collecting vessel, bellows
91 feed line, collecting vessel
910 valve of the feed line, collecting vessel
92 discharge line, collecting vessel
920 valve of the discharge line, collecting vessel
10 vacuum pump
101 feed line, vacuum pump
1010 valve of the feed line, vacuum pump
102 discharge line, vacuum pump
11 drying unit

1. A cooling system for the liquid immersion cooling of electronic components, the cooling system comprising:
a vessel having an interior fillable with two-phase liquid heat transfer fluid, in a liquid phase of which electronic components can be immersed, the vessel having a gas space above a surface of the liquid heat transfer fluid;
a heat exchanger device in the gas space of the vessel for forming liquid heat transfer fluid; and
a condenser unit arranged outside the vessel, the condenser unit being connected by a fluid line as a feed line and return line to the gas space of the vessel for mass transfer of gaseous medium to the condenser unit and condensed heat transfer fluid to the vessel, the condenser unit having an outlet, via which outlet a residual gas phase can be discharged,
the fluid line as the feed line and return line of the condenser unit being a single tube line with a suitable line cross section or a double-tube line, and being connected to the vessel.

2. The cooling system as claimed in claim 1, wherein the fluid line has a structured internal surface.

3. The cooling system as claimed in claim 2, wherein that the structured internal surface of the fluid line has helically encircling ribbing.

4. The cooling system as claimed in claim 1, wherein the fluid line is a tube line or double-tube line running at an angle of inclination to an action of gravity.

5. The cooling system as claimed in claim 4, wherein the angle of inclination of the fluid line to the action of gravity is at least 2°.

6. The cooling system as claimed in claim 1, including valves, and the feed line, return line and/or the outlet can be closed or opened individually or in combination with one another by the valves.

7. The cooling system as claimed in claim 1, including a collecting vessel, via which collecting vessel the residual gas phase can be discharged, the collecting vessel being connected downstream of the outlet.

8. The cooling system as claimed in claim 7, further including a drying unit for separating water vapor from the gas phase is arranged between the outlet and the collecting vessel.

9. The cooling system as claimed in claim 1, including vacuum pump, via which vacuum pump the residual gas phase can be discharged, the vacuum pump being connected downstream of the outlet.

10. The cooling system as claimed in claim 1, wherein the heat exchanger device and the condenser unit have a common supply unit for a single-phase heat transfer medium for cooling.

11. The cooling system as claimed in claim 10, wherein a quantity distribution of the single-phase heat transfer medium for cooling for the heat exchanger device and the condenser unit of the common supply unit is accomplished by active control of a volume flow of the single-phase heat transfer medium.

12. The cooling system as claimed in claim 1, including a cooling device arranged at least partially on the fluid line.
